(19) United States
(12) Patent Application Publication
(10) Pub. No.: US 2025/0366336 A1
(43) Pub. Date: Nov. 27, 2025

(54) DISPLAY DEVICE

(71) Applicant: Samsung Display Co., Ltd., Yongin-si (KR)

(72) Inventors: DONGIL YOO, Yongin-si (KR); KWANGSU PARK, Yongin-si (KR); JUNG SUK BANG, Yongin-si (KR); MYUNGHUN LIM, Yongin-si (KR)

(21) Appl. No.: 19/196,688

(22) Filed: May 1, 2025

(30) Foreign Application Priority Data
May 27, 2024 (KR) 10-2024-0068555

(51) Int. Cl. H10K 59/35; H10K 59/122; H10K 59/131; H10K 59/60

(52) U.S. Cl. CPC H10K 59/353; H10K 59/122; H10K 59/131; H10K 59/60

(57) ABSTRACT

A display device includes a base layer including a display area and a non-display area adjacent to the display area; unit elements, each including a first display element configured to emit a first color light, a second display element configured to emit a second color light different from the first color light, a third-first display element configured to emit a third color light different from the first and second color lights, a third-second display element configured to emit the third color light different from the first and second color lights, and a light sensing element surrounded by the first, second, third-first, and third-second display elements and located in the display area; and a pixel definition layer, first, second, third-first, and third-second display openings in the pixel defining layer and overlapping the first, second, third-first, and third-second display elements and a sensing opening in the pixel defining layer.

### CROSS-REFERENCE TO RELATED APPLICATION(S)

This application claims priority to and the benefit of Korean Patent Application No. 10-2024-0068555, filed on May 27, 2024, in the Korean Intellectual Property Office, the entire disclosure of which is incorporated by reference herein.

### BACKGROUND

### 1. Field

The present disclosure relates to a display device. More particularly, the present disclosure relates to a display device including a light sensing element.

### 2. Description of Related Art

Multimedia display devices, such as televisions, mobile phones, tablet computers, navigation devices, and game devices, include a display panel displaying an image and a sensor sensing an external input to generate an electrical signal. The display device includes a light sensor that senses a light incident thereto to recognize a user's fingerprint.

### SUMMARY

The present disclosure provides a display device capable of preventing a light sensing element from overlapping a connection line.

Embodiments of the present disclosure provide a display device including a base layer comprising a display area and a non-display area adjacent to the display area; unit elements, each of the unit elements comprising a first display element configured to emit a first color light, a second display element configured to emit a second color light different from the first color light, a third-first display element configured to emit a third color light different from the first and second color lights, a third-second display element configured to emit the third color light different from the first and second color lights, and a light sensing element surrounded by the first, second, third-first, and third-second display elements and located in the display area; and a pixel definition layer, first, second, third-first, and third-second display openings in the pixel defining layer and overlapping the first, second, third-first, and third-second display elements and a sensing opening in the pixel defining layer and overlapping the light sensing element, wherein the first, second, third-first, and third-second display openings and the sensing opening have a circular shape when viewed in a plane, a center of the first display opening and a center of the third-second display opening are at a lower right position with respect to the sensing opening, and a center of the second display opening and a center of the third-first display opening are at an upper left position with respect to the sensing opening. In one or more embodiments, the center of the first display opening and the center of the third-second display opening are asymmetrically located with respect to the sensing opening.

In one or more embodiments, the center of the second display opening and the center of the third-first display opening are asymmetrically located with respect to the sensing opening.

In one or more embodiments, a distance from the center of the second display opening to the center of the third-first display opening is smaller than a distance from the center of the second display opening to the center of the third-second display opening when viewed in the plane.

In one or more embodiments, a distance from the center of the first display opening to the center of the third-first display opening is greater than a distance from the center of the first display opening to the center of the third-second display opening when viewed in the plane.

In one or more embodiments, a distance from the center of the second display opening to the center of the third-first display opening is smaller than a distance from the center of the first display opening to the center of the third-first display opening when viewed in the plane.

In one or more embodiments, a distance from the center of the second display opening to the center of the third-second display opening is greater than a distance from the center of the first display opening to the center of the third-second display opening when viewed in the plane.

In one or more embodiments, the center of the sensing opening is at a right side with respect to an imaginary line passing through the center of the third-first display opening and the center of the third-second display opening when viewed in the plane.

In one or more embodiments, the center of the sensing opening is at an upper side with respect to an imaginary line passing through the center of the first display opening and the center of the second display opening when viewed in the plane.

In one or more embodiments, the unit elements include first row unit elements arranged along a first direction when viewed in the plane and second row unit elements spaced from the first row unit elements in a second direction intersecting the first direction and arranged in the first direction when viewed in the plane.

In one or more embodiments, the second row unit elements are shifted from the first row unit elements along a diagonal direction intersecting the first and second directions.

In one or more embodiments, the second display opening has a diameter greater than a diameter of the first display opening when viewed in the plane.

In one or more embodiments, the first display opening has the diameter greater than a diameter of the third-first display opening when viewed in the plane.

In one or more embodiments, the diameter of the third-first display opening is equal to a diameter of the third-second display opening when viewed in the plane.

In one or more embodiments, each of the first, second, third-first, and third-second display openings has a diameter greater than a diameter of the sensing opening when viewed in the plane.

In one or more embodiments, a distance between the sensing opening and each of the first, second, third-first, and third-second display openings is equal to or greater than about 16.5 micrometers and equal to or smaller than about 23 micrometers when viewed in the plane.

In one or more embodiments, a distance from the center of the third-first display opening to the center of the sensing opening is different from a distance from the center of the third-second display opening to the center of the sensing opening when viewed in the plane.

In one or more embodiments, the display device further includes first, second, third-first, and third-second connection lines.

In one or more embodiments, each of the first, second, third-first, and third-second display elements includes a first electrode, a light emitting layer on the first electrode, and a second electrode on the light emitting layer.

In one or more embodiments, each of the first, second, third-first, and third-second connection lines extends from the first electrode of a corresponding display element from among the first, second, third-first, and third-second display elements.

In one or more embodiments, the first, second, third-first, and third-second connection lines do not overlap the light sensing element.

In one or more embodiments, the display device further includes first, second, third-first, and third-second driving circuits and first, second, third-first, and third-second data lines.

In one or more embodiments, the first, second, third-first, and third-second data lines are connected to the first, second, third-first, and third-second driving circuits, respectively.

In one or more embodiments, the first, second, third-first, and third-second connection lines are connected to the first, second, third-first, and third-second driving circuits, respectively.

In one or more embodiments, the display device further includes a sensor data line, a sensor driving circuit connected to the sensor data line, and a sensor connection line connecting the light sensing element and the sensor driving circuit.

In one or more embodiments, the first color light is a red light, the second color light is a blue light, and the third color light is a green light.

In one or more embodiments, the light sensing element senses fingerprint information or pulse information.

In one or more embodiments, a display device including a base layer comprising a display area and a non-display area adjacent to the display area; unit elements, each of the unit elements comprising a first display element, a second display element, a third-first display element, a third-second display element, and a light sensing element surrounded by the first, second, third-first, and third-second display elements and located in the display area; and a pixel definition layer, first, second, third-first, and third-second display openings in the pixel defining layer and respectively overlapping the first, second, third-first, and third-second display elements, and a sensing opening in the pixel defining layer and overlapping the light sensing element, wherein the first, second, third-first, and third-second display openings and the sensing opening have a circular shape when viewed in a plane, and each of a first angle between a first line segment connecting a center of the sensing opening and a center of the first display opening and a third-first line segment connecting the center of the sensing opening and a center of the third-first display opening and a third angle between a second line segment connecting the center of the sensing opening and a center of the second display opening and a third-second line segment connecting the center of the sensing opening and a center of the third-second display opening is an obtuse angle. Each of a second angle between the second line segment and the third-first line segment and a fourth angle between the first line segment and the third-second line segment is an acute angle.

A sum of the first to fourth angles is 360 degrees.

A sum of the first angle and the second angle is equal to or greater than 180 degrees.

A sum of the third angle and the fourth angle is equal to or smaller than 180 degrees.

A sum of the second angle and the third angle is equal to or smaller than 180 degrees.

A sum of the first angle and the fourth angle is equal to or greater than 180 degrees.

According to the above, the display elements are asymmetrically disposed with respect to the light sensing element, and thus, the distances between the light sensing element and each of the display elements are sufficiently secured.

### BRIEF DESCRIPTION OF THE DRAWINGS

The above and other aspects an features of embodiments of the present disclosure will become readily apparent with reference to the following detailed description when considered in conjunction with the accompanying drawings wherein:

FIG. 1 is a perspective view of a display device according to one or more embodiments of the present disclosure;

FIG. 2 is a cross-sectional view of a display device according to one or more embodiments of the present disclosure;

FIG. 3 is a cross-sectional view of a display panel according to one or more embodiments of the present disclosure;

FIG. 4 is a block diagram of a display device according to one or more embodiments of the present disclosure;

FIG. 5 is an equivalent circuit diagram of one pixel and a light sensor adjacent to the pixel according to one or more embodiments of the present disclosure;

FIG. 6 is a cross-sectional view of a portion of a display panel according to one or more embodiments of the present disclosure;

FIG. 7 is a cross-sectional view of a portion of a display panel according to one or more embodiments of the present disclosure;

FIG. 8A is a plan view of display openings and sensing openings according to one or more embodiments of the present disclosure;

FIG. 8B is a plan view of a reference unit opening according to a comparative example;

FIG. 8C is an enlarged plan view of one unit area shown in FIG. 8A;

FIG. 8D is a plan view of arrangement of openings and connection lines according to one or more embodiments of the present disclosure; and

FIG. 9 is a cross-sectional view illustrating a process of obtaining fingerprint information that is biometric information using a light sensor.

### DETAILED DESCRIPTION

The present disclosure may be variously modified and realized in many different forms, and thus specific embodiments will be shown as examples in the drawings and described in detail hereinbelow. However, the present disclosure may not be limited to the specific disclosed forms, and may be construed to include all modifications, equivalents, and/or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and/or the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

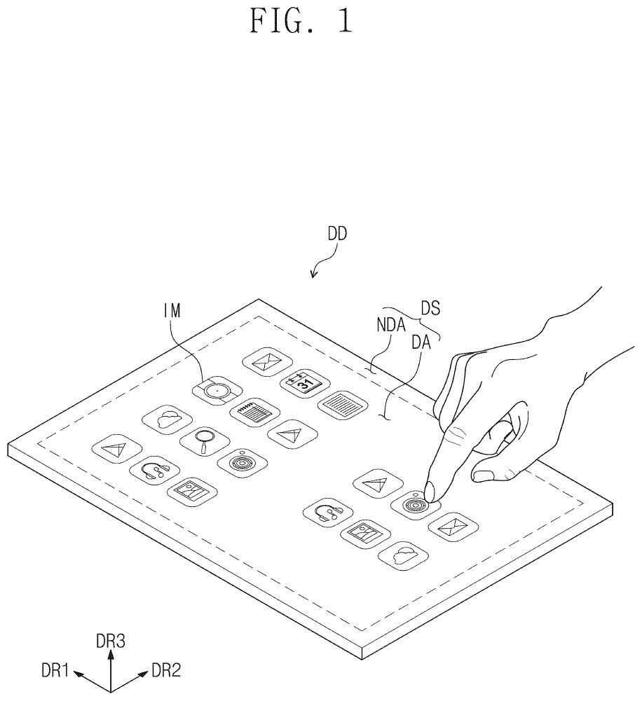

FIG. 1 is a perspective view of a display device DD according to one or more embodiments of the present disclosure.

The display device DD may be activated in response to electrical signals. The display device DD may be applied to various electronic items, such as a notebook computer, a television set, a personal digital assistant, a car navigation unit, a game unit, a smartphone, a tablet computer, a camera, etc.

Referring to FIG. 1, the display device DD may have a rectangular shape with long sides in a first direction DR1 and short sides in a second direction DR2 crossing the first direction DR1. However, the shape of the display device DD should not be limited to the rectangular shape, and the display device DD may have a variety of shapes, such as a circular shape, a polygonal shape, and/or the like.

Hereinafter, a direction substantially perpendicular to a plane defined by the first direction DR1 and the second direction DR2 is referred to as a third direction DR3. In the following descriptions, the expression “when viewed in a plane” or “in a plan view” may mean a state of being viewed in the third direction DR3.

An upper surface of the display device DD may be defined as a display surface DS. The display device DD may include the plane defined by the first direction DR1 and the second direction DR2. An image IM generated by the display device DD may be provided to a user through the display surface DS. FIG. 1 illustrates icon images as a representative example of the image IM.

The display surface DS may include a display area DA through which the image IM is displayed and a non-display area NDA adjacent to the display area DA and disposed along an edge or a periphery of the display area DA. The non-display area NDA may be an area through which the image IM is not displayed. The non-display area NDA may surround the display area DA, however, the present disclosure should not be limited thereto or thereby, and the non-display area NDA may not be defined at one side of the display area DA.

The display device DD may sense an external input applied thereto from the outside. The external input may include a variety of external inputs provided from the outside. For example, the external input may include an external input (e.g., a hovering input) applied when in proximity to or approaching close to the display device DD at a suitable distance (e.g., a predetermined distance) as well as a touch input by a user's body, e.g., a hand of the user US-F or by an additional device, e.g., an active pen, a digitizer, and/or the like. In addition, the external input may include various forms, such as force, pressure, temperature, and/or light.

The display device DD may sense biometric information of the user, which is applied thereto from the outside. The display device DD may include a biometric information sensing area defined in the display surface DS to sense the biometric information of the user. The biometric information sensing area may be defined in an entire portion of the display area DA or may be defined in a portion of the display area DA. FIG. 1 illustrates a structure in which the entire portion of the display area DA is used as the biometric information sensing area, however, the present disclosure should not be limited thereto or thereby. As an example, only a portion of the display area DA may be defined as the area in which the biometric information is sensed.

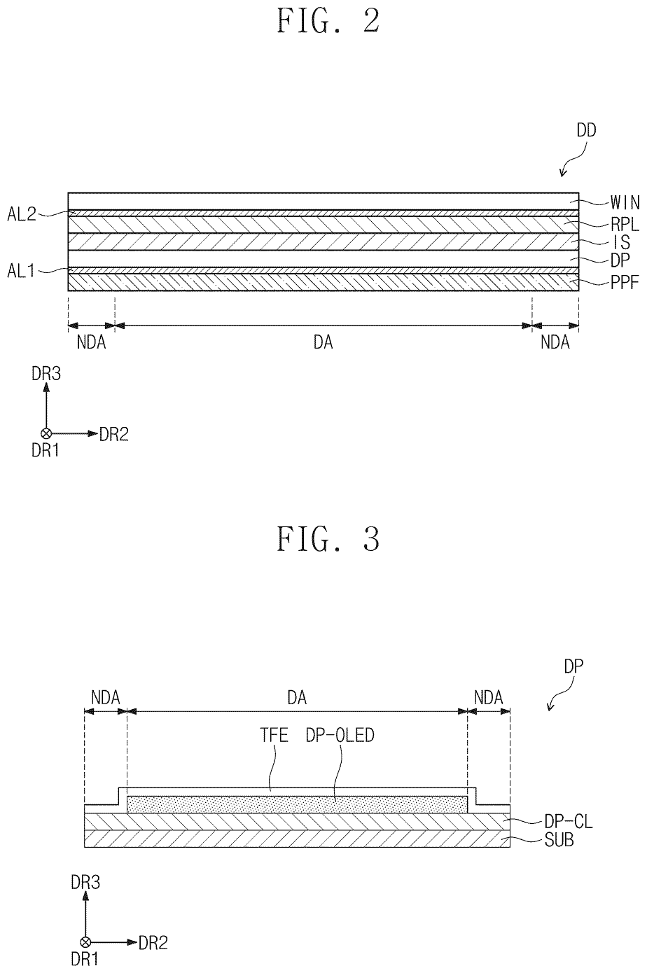

FIG. 2 is a cross-sectional view of the display device DD according to one or more embodiments of the present disclosure.

Referring to FIG. 2, the display device DD may include a display panel DP, an input sensor IS, an anti-reflective layer RPL, a window WIN, a panel protective film PPF, and first and second adhesive layers AL1 and AL2.

The display panel DP may be a light emitting type display panel, however, it should not be particularly limited. As an example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot and/or a quantum rod. Hereinafter, the organic light emitting display panel will be described as a representative example of the display panel DP.

The input sensor IS may be disposed on the display panel DP. The input sensor IS may include a plurality of sensors to sense the external input by a capacitive method. The input sensor IS may be directly manufactured on the display panel DP when the display device DD is manufactured, however, it should not be limited thereto or thereby. According to one or more embodiments, the input sensor IS may be attached to the display panel DP by an adhesive layer after being manufactured separately from the display panel DP.

The anti-reflective layer RPL may be disposed on the input sensor IS. The anti-reflective layer RPL may be formed directly on the input sensor IS when the display device DD is manufactured. The anti-reflective layer RPL may include color filters and may further include a black matrix.

According to one or more embodiments, the anti-reflective layer RPL may be attached to the input sensor IS by an adhesive layer after being manufactured as a separate panel. The anti-reflective layer RPL may include an optical film such as a polarizing film. The anti-reflective layer RPL may reduce a reflectance with respect to an external light incident to the display panel DP from the above of the display device DD. Due to the anti-reflective layer RPL, the external light may not be perceived by the user.

The window WIN may be disposed on the anti-reflective layer RPL and may transmit the image IM (refer to FIG. 1) provided from the display device DD to the outside. The window WIN may protect the display panel DP, the input sensor IS, and the anti-reflective layer RPL from external scratches and/or impacts.

The panel protective film PPF may be disposed under the display panel DP. The panel protective film PPF may protect a lower portion of the display panel DP. The panel protective film PPF may include a flexible plastic material such as polyethylene terephthalate (PET).

The display device DD may further include the first adhesive layer AL1 disposed between the display panel DP and the panel protective film PPF and the second adhesive layer AL2 disposed between the window WIN and the anti-reflective layer RPL.

The panel protective film PPF may be attached to the display panel DP by the first adhesive layer AL1. The window WIN may be attached to the anti-reflective layer RPL by the second adhesive layer AL2. The first and second adhesive layers AL1 and AL2 may include an optically clear adhesive (OCA), an optically clear adhesive resin (OCR), and/or a pressure sensitive adhesive (PSA).

In the above descriptions, components of the display device DD are described when viewed in a cross-section, however, the present disclosure is not limited thereto or thereby. As an example, the anti-reflective layer RPL, the input sensor IS, or the first and second adhesive layers AL1 and AL2 may be omitted.

FIG. 3 is a cross-sectional view of the display panel DP according to one or more embodiments of the present disclosure.

Referring to FIG. 3, the display panel DP may include a base layer SUB, a circuit element layer DP-CL disposed on the base layer SUB, a display element layer DP-OLED disposed on the circuit element layer DP-CL, and an encapsulation layer TFE disposed on the display element layer DP-OLED.

The base layer SUB may be disposed at a lowermost position of the display panel DP to provide a base surface on which other components of the display panel DP are disposed. The base layer SUB may include a synthetic resin layer. The synthetic resin layer may include a heat-curable resin. The synthetic resin layer may be a polyimide-based resin layer, but it may not be particularly limited. The synthetic resin layer may include an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and/or a perylene-based resin. According to one or more embodiments, the base layer SUB may include a glass substrate, a metal substrate, and/or an organic/inorganic composite material substrate.

The circuit element layer DP-CL may include a plurality of insulating layers and a circuit element. The insulating layers may include at least one inorganic layer and at least one organic layer. The circuit element may include signal lines, driving circuits, and/or the like. The driving circuits may include a pixel driving circuit and/or a sensor driving circuit.

The insulating layer and the circuit element may be formed by forming an insulating layer, a semiconductor layer, and a conductive layer through coating and depositing processes and selectively patterning the insulating layer, the semiconductor layer, and the conductive layer through photolithography and etching processes. Thus, the semiconductor pattern, the conductive pattern, and the signal line may be formed on the circuit element layer DP-CL.

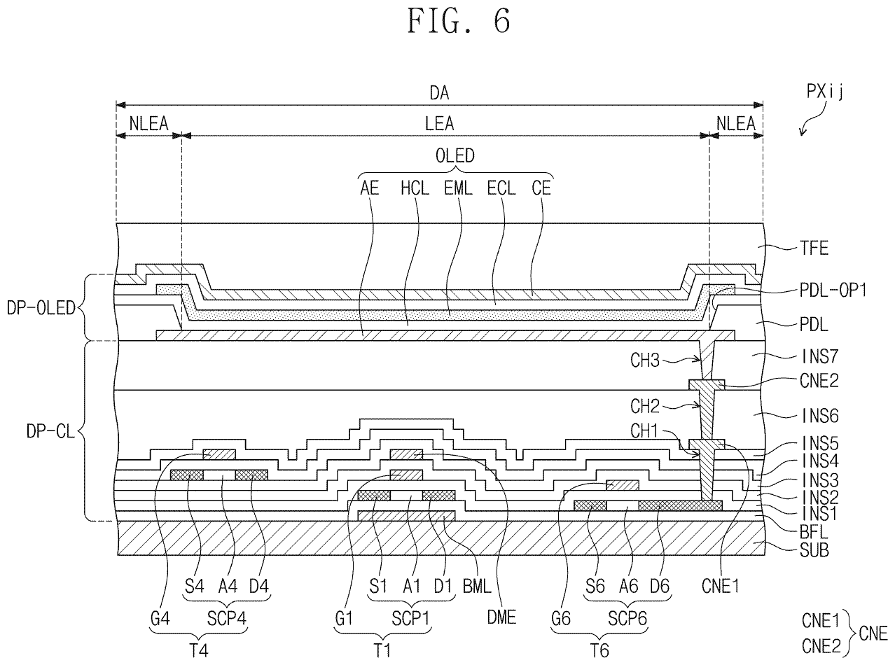

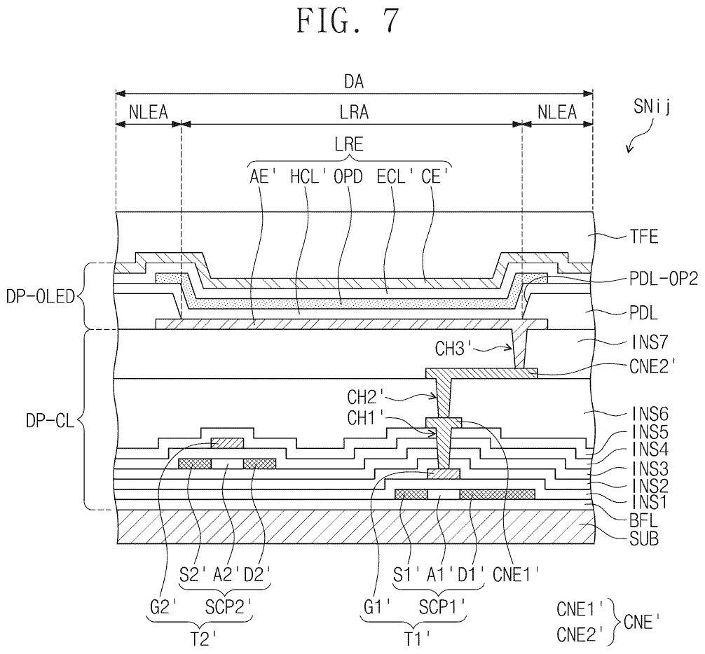

The display element layer DP-OLED may be disposed on the circuit element layer DP-CL. The display element layer DP-OLED may include a pixel definition layer PDL (refer to FIG. 6), a display element OLED (refer to FIG. 6), and a light sensing element LRE (refer to FIG. 7).

The encapsulation layer TFE may be disposed on the display element layer DP-OLED to cover the display element layer DP-OLED. The encapsulation layer TFE may prevent moisture and/or oxygen from entering the display element layer DP-OLED. The encapsulation layer TFE may include an inorganic layer, an organic layer, and an inorganic layer, which are sequentially stacked.

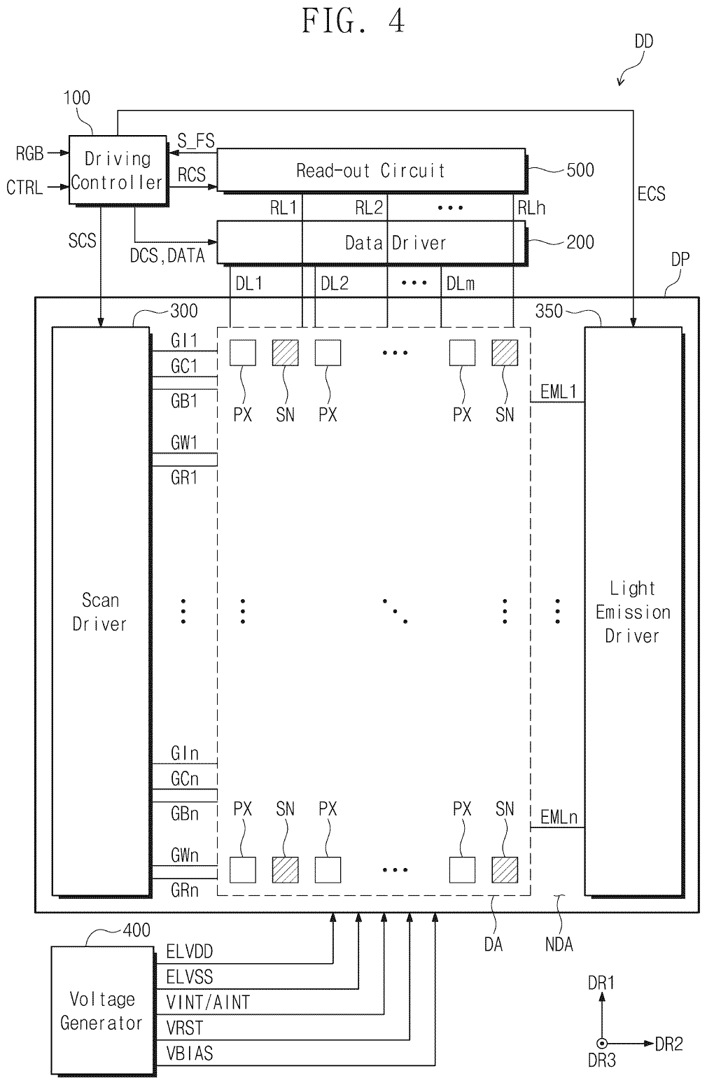

FIG. 4 is a block diagram of the display device DD according to one or more embodiments of the present disclosure.

Referring to FIG. 4, the display device DD may include the display panel DP, a driving controller 100, and a driving circuit. As an example, the driving circuit may include a data driver 200, a scan driver 300, a light emission driver 350, a voltage generator 400, and a read-out circuit 500. The voltage generator 400 and the read-out circuit 500 may be implemented in a single driving chip with the driving controller 100.

The display panel DP may include a plurality of pixels PX arranged in the display area DA and a plurality of light sensors SN arranged in the display area DA. FIG. 4 shows a structure in which each of the light sensors SN is arranged between two pixels PX adjacent to each other, however, the arrangement relationship between the light sensors SN and the pixels PX may not be limited thereto or thereby.

The display panel DP may include initialization scan lines GI1 to GIn, compensation scan lines GC1 to GCn, bias scan lines GB1 to GBn, write scan lines GW1 to GWn, light emission control lines EML1 to EMLn, reset scan lines GR1 to GRn, data lines DL1 to DLm, and read-out lines RL1 to RLh.

The initialization scan lines GI1 to GIn, the compensation scan lines GC1 to GCn, the bias scan lines GB1 to GBn, the write scan lines GW1 to GWn, the light emission control lines EML1 to EMLn, and the reset scan lines GR1 to GRn may extend in the second direction DR2. The data lines DL1 to DLm and the read-out lines RL1 to RLh may extend in the first direction DR1.

The pixels PX may be electrically connected to the initialization scan lines GI1 to GIn, the compensation scan lines GC1 to GCn, the write scan lines GW1 to GWn, the bias scan lines GB1 to GBn, the light emission control lines EML1 to EMLn, and the data lines DL1 to DLm. However, the number of the signal lines connected to each of the pixels PX should not be limited thereto or thereby.

The light sensors SN may be electrically connected to the write scan lines GW1 to GWn, the reset scan lines GR1 to GRn, and the read-out lines RL1 to RLh. The number of the signal lines connected to each of the light sensors SN may vary.

The driving controller 100 may receive an image signal RGB and control signals CTRL. The driving controller 100 may convert a data format of the image signal RGB to a data format appropriate to an interface between the data driver 200 and the driving controller 100 to generate an image data signal DATA. The driving controller 100 may generate a first control signal DCS, a second control signal SCS, a third control signal ECS, and a fourth control signal RCS.

The data driver 200 may receive the first control signal DCS and the image data signal DATA from the driving controller 100. The data driver 200 may convert the image data signal DATA to data signals and may output the data signals to the data lines DL1 to DLm described later. The data signals may be analog voltages corresponding to grayscale values of the image data signal DATA.

The scan driver 300 may receive the second control signal SCS from the driving controller 100. Responsive to the second control signal SCS, the scan driver 300 may output initialization scan signals to the initialization scan lines GI1 to GIn and may output compensation scan signals to the compensation scan lines GC1 to GCn. In addition, responsive to the second control signal SCS, the scan driver 300 may output write scan signals to the write scan lines GW1 to GWn and may output bias scan signals to the bias scan lines GB1 to GBn. Further, the scan driver 300 may output reset scan signals to the reset scan lines GR1 to GRn in response to the second control signal SCS.

The light emission driver 350 may receive the third control signal ECS from the driving controller 100. The light emission driver 350 may output light emission control signals to the light emission control lines EML1 to EMLn in response to the third control signal ECS. According to one or more embodiments, alternatively, the scan driver 300 may be connected to the light emission control lines EML1 to EMLn. In this case, the light emission driver 350 may be omitted, and the scan driver 300 may output the light emission control signals to the light emission control lines EML1 to EMLn.

The read-out circuit 500 may receive the fourth control signal RCS from the driving controller 100. The read-out circuit 500 may receive sensing signals from the read-out lines RL1 to RLh in response to the fourth control signal RCS. The read-out circuit 500 may process the sensing signals from the read-out lines RL1 to RLh and may provide the processed sensing signals S_FS to the driving controller 100. The driving controller 100 may recognize the biometric information based on the sensing signals S_FS.

The voltage generator 400 may generate voltages required to operate the display panel DP. In the present embodiment, the voltage generator 400 may generate a first driving voltage ELVDD, a second driving voltage ELVSS having a level lower than a level of the first driving voltage ELVDD, a first initialization voltage VINT, a second initialization voltage AINT, a reset voltage VRST, and a bias voltage VBIAS.

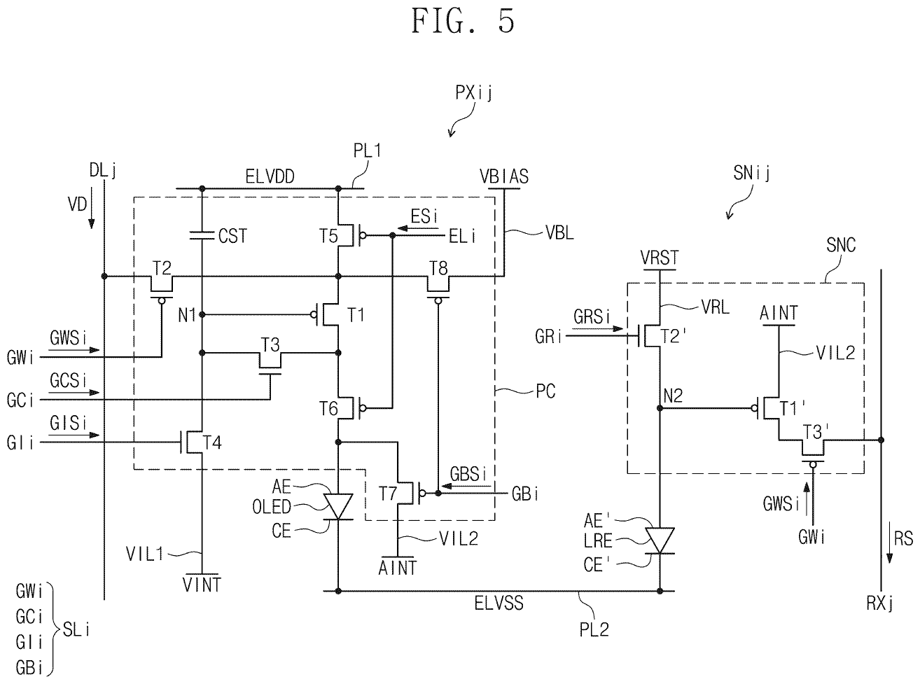

FIG. 5 is an equivalent circuit diagram of one pixel PXij and a light sensor SNij adjacent to the pixel PXij according to one or more embodiments of the present disclosure.

As an example, the pixel PXij shown in FIG. 5 is connected to i-th scan lines SLi, an i-th light emission line ELi, and a j-th data line DLj. Because the pixels PX (refer to FIG. 4) may have substantially the same configuration as each other, the circuit configuration of the pixel PXij will be described in detail, and detailed descriptions of the other pixels will be omitted.

In addition, FIG. 5 shows the light sensor SNij connected to an i-th reset scan line GRi and a j-th read-out line RXj as a representative example. Each of “i” and “j” is a natural number. The i-th scan lines SLi may include an i-th initialization scan line GIi, an i-th compensation scan line GCi, an i-th bias scan line GBi, and an i-th write scan line GWi.

Referring to FIG. 5, the pixel PXij may include a pixel driving circuit PC (or a first driving circuit) and the display element OLED electrically connected to the pixel driving circuit PC. The display element OLED may be turned on or turned off by the pixel driving circuit PC.

The pixel driving circuit PC may include transistors T1 to T8 and a capacitor CST. The transistors T1 to T8 and the capacitor CST may control an amount of current flowing through the display element OLED. That is, the pixel driving circuit PC may control the amount of current flowing through the display element OLED in response to a data signal. The display element OLED may emit a light with a suitable luminance (e.g., a predetermined luminance) corresponding to the amount of current provided from the pixel driving circuit PC.

The i-th write scan line GWi may receive an i-th write scan signal GWSi, and the i-th compensation scan line GCi may receive an i-th compensation scan signal GCSi. The i-th initialization scan line GIi may receive an i-th initialization scan signal GISi, and the i-th bias scan line GBi may receive an i-th bias scan signal GBSi. The i-th reset scan line GRi may receive an i-th reset scan signal GRSi. The i-th light emission line ELi may receive an i-th light emission signal ESi.

A first initialization line VIL1 may receive the first initialization voltage VINT, and a second initialization line VIL2 may receive the second initialization voltage AINT. A bias line VBL may receive the bias voltage VBIAS. A first power line PL1 may receive the first driving voltage ELVDD, and a second power line PL2 may receive the second driving voltage ELVSS. The display element OLED may be connected to the second power line PL2. A reset line VRL may receive the reset voltage VRST.

Each of the transistors T1 to T8 may include a source (or a source terminal), a drain (or a drain terminal), and a gate (or a gate terminal). Hereinafter, for the sake of explanation, one of the source and the drain may be referred to as a first electrode, and the other one of the source and the drain may be referred to as a second electrode. In addition, the gate may be referred to as a gate electrode or a control electrode.

The transistors T1 to T8 may include first, second, third, fourth, fifth, sixth, seventh, and eighth transistors T1, T2, T3, T4, T5, T6, T7, and T8. Each of the first, second, and fifth to eighth transistors T1, T2, and T5 to T8 may be a PMOS transistor. Each of the third and fourth transistors T3 and T4 may be an NMOS transistor.

The first transistor T1 may be defined as a driving transistor, and the second transistor T2 may be defined as a switching transistor. The third transistor T3 may be defined as a compensation transistor. The fourth transistor T4 and the seventh transistor T7 may be defined as an initialization transistor. The fifth transistor T5 and the sixth transistor T6 may be defined as a light emission control transistor. The eighth transistor T8 may be defined as a bias transistor.

The display element OLED may include an organic light emitting diode. The display element OLED may include a first electrode, a second electrode, and a light emitting layer disposed between the first electrode and the second electrode. In the present embodiment, for the convenience of explanation, the first electrode will be described as an anode AE, and the second electrode will be described as a cathode CE. The anode AE may be electrically connected to the first power line PL1 through the sixth, first, and fifth transistors T6, T1, and T5. The cathode CE may be electrically connected to the second power line PL2.

The first transistor T1 may be disposed between the fifth transistor T5 and the sixth transistor T6 and may be connected to the fifth transistor T5 and the sixth transistor T6. The first transistor T1 may be connected to the first power line PL1 through the fifth transistor T5 and may be connected to the anode AE through the sixth transistor T6.

The first transistor T1 may include the first electrode connected to the first power line PL1 through the fifth transistor T5, the second electrode connected to the anode AE through the sixth transistor T6, and the gate electrode connected to a first node N1.

The first electrode of the first transistor T1 may be connected to the fifth transistor T5, and the second electrode of the first transistor T1 may be connected to the sixth transistor T6. The first transistor T1 may control the amount of current flowing through the display element OLED based on a voltage of the first node N1, which is applied to the gate electrode of the first transistor T1.

The second transistor T2 may be disposed between the first transistor T1 and the j-th data line DLj and may be connected to the first electrode of the first transistor T1 and the j-th data line DLj. The second transistor T2 may include the first electrode connected to the j-th data line DLj, the second electrode connected to the first electrode of the first transistor T1, and the gate electrode connected to the i-th write scan line GWi.

The second transistor T2 may be turned on in response to the i-th write scan signal GWSi applied thereto through the i-th write scan line GWi to electrically connect the j-th data line DLj and the first electrode of the first transistor T1. The second transistor T2 may perform a switching operation to provide a data voltage VD provided through the j-th data line DLj to the first electrode of the first transistor T1.

The third transistor T3 may be connected to the second electrode of the first transistor T1 and the first node N1. The third transistor T3 may include the first electrode connected to the second electrode of the first transistor T1, the second electrode connected to the first node N1, and the gate electrode connected to the i-th compensation scan line GCi.

The third transistor T3 may be turned on in response to the i-th compensation scan signal GCSi applied thereto through the i-th compensation scan line GCi to electrically connect the second electrode of the first transistor T1 and the gate electrode of the first transistor T1. When the third transistor T3 is turned on, the first transistor T1 and the third transistor T3 may be connected to each other in a diode configuration (e.g., the first transistor T1 may be diode-connected).

The fourth transistor T4 may be connected to the first node N1. The fourth transistor T4 may include the first electrode connected to the first node N1, the second electrode connected to the first initialization line VIL1, and the gate electrode connected to the i-th initialization scan line GIi. The fourth transistor T4 may be turned on in response to the i-th initialization scan signal GISi applied thereto through the i-th initialization scan line GIi to provide the first initialization voltage VINT from the first initialization line VIL1 to the first node N1.

The fifth transistor T5 may include the first electrode connected to the first power line PL1, the second electrode connected to the first electrode of the first transistor T1, and the gate electrode connected to the i-th light emission line ELi. The sixth transistor T6 may include the first electrode connected to the second electrode of the first transistor T1, the second electrode connected to the anode AE, and the gate electrode connected to the i-th light emission line ELi.

The fifth transistor T5 and the sixth transistor T6 may be turned on in response to the i-th light emission signal ESi applied thereto through the i-th light emission line ELi. Due to the turned-on fifth and sixth transistors T5 and T6, the first driving voltage ELVDD may be provided to the display element OLED, and thus, a driving current may flow through the display element OLED. Accordingly, the display element OLED may emit a light.

The seventh transistor T7 may include the first electrode connected to the anode AE, the second electrode connected to the second initialization line VIL2, and the gate electrode connected to the i-th bias scan line GBi. The seventh transistor T7 may be turned on in response to the i-th bias scan signal GBSi applied thereto through the i-th bias scan line GBi to provide the second initialization voltage AINT provided through the second initialization line VIL2 to the anode AE of the display element OLED.

According to one or more embodiments, the seventh transistor T7 may be omitted. According to the present embodiment, the second initialization voltage AINT may have a level different from that of the first initialization voltage VINT, however, it may not be limited thereto or thereby. According to one or more embodiments, the second initialization voltage AINT may have substantially the same level as the first initialization voltage VINT.

The seventh transistor T7 may improve a black color representation of the pixel PXij. In detail, when the seventh transistor T7 is turned on, a parasitic capacitance of the display element OLED is discharged. Accordingly, when implementing a black luminance, the display element OLED does not emit the light due to a leakage of electrical current from the first transistor T1, and thus the black color representation may be improved.

The capacitor CST may include a first electrode connected to the first power line PL1 and a second electrode connected to the first node N1. When the fifth transistor T5 and the sixth transistor T6 are turned on, an amount of current flowing through the first transistor T1 may be determined based on a voltage charged in the capacitor CST.

The eighth transistor T8 may include the first electrode connected to the bias line VBL, the second electrode connected to the first electrode of the first transistor T1, and the gate electrode connected to the i-th bias scan line GBi. According to one or more embodiments, the eighth transistor T8 may be omitted.

The eighth transistor T8 may be turned on in response to the i-th bias scan signal GBSi and may apply the bias voltage VBIAS to the first electrode of the first transistor T1. As the bias voltage VBIAS is applied to the first transistor T1, a shift of the hysteresis curve of the first transistor T1 may be prevented.

The light sensor SNij may include a sensor driving circuit SNC (or a second driving circuit) and the light sensing element LRE electrically connected to the sensor driving circuit SNC. The sensor driving circuit SNC may sense an operation of the light sensing element LRE.

The sensor driving circuit SNC may include a first sensing transistor T1′, a second sensing transistor T2′, and a third sensing transistor T3′. Each of the first and third sensing transistors T1′ and T3′ may be a PMOS transistor, and the second sensing transistor T2′ may be an NMOS transistor.

The light sensing element LRE may be a photodiode. The light sensing element LRE may convert an optical energy incident thereto from the outside to an electrical energy. The light sensing element LRE may include a first electrode, a second electrode, and a photoelectric conversion layer disposed between the first electrode and the second electrode.

In the present embodiment, for the sake of explanation, the first electrode will be described as an anode AE′, and the second electrode will be described as a cathode CE′. The anode AE′ may be connected to a second node N2, and the cathode CE′ may be connected to the second power line PL2. In one or more embodiments, to distinguish the anode AE and the cathode CE of the display element OLED from the anode AE′ and the cathode CE′ of the light sensing element LRE, the anode AE and the cathode CE of the display element OLED may be referred to as the first electrode and the second electrode, respectively, and the anode AE′ and the cathode CE′ of the light sensing element LRE may be referred to as a first-first electrode and a second-first electrode, respectively.

The first sensing transistor T1′ may be connected to the light sensing element LRE, the second sensing transistor T2′, and the third sensing transistor T3′. The first sensing transistor T1′ may include a first electrode receiving the second initialization voltage AINT, a gate electrode connected to a second node N2, and a second electrode connected to the third sensing transistor T3′. The first electrode of the first sensing transistor T1′ may be connected to the second initialization line VIL2 to receive the second initialization voltage AINT. The second sensing transistor T2′ may include a first electrode connected to the second node N2, a gate electrode connected to the i-th reset scan line GRi, and a second electrode connected to the reset line VRL. The third sensing transistor T3′ may include a first electrode connected to the second electrode of the first sensing transistor T1′, a gate electrode connected to the i-th write scan line GWi, and a second electrode connected to the j-th read-out line RXj. The third sensing transistor T3′ may be turned on in response to the i-th write scan signal GWSi applied thereto through the i-th write scan line GWi.

The second sensing transistor T2′ may be turned on in response to the i-th reset scan signal GRSi applied thereto through the i-th reset scan line GRi. The turned-on second sensing transistor T2′ may receive the reset voltage VRST and may provide the reset voltage VRST to the second node N2. The second node N2 may be reset by the reset voltage VRST.

The i-th write scan signal GWSi may be applied to the gate electrode of the third sensing transistor T3′ to turn on the third sensing transistor T3′. The first sensing transistor T1′ may be connected to the j-th read-out line RXj through the turned-on third sensing transistor T3′.

The light sensing element LRE may convert the light incident thereto to an electrical signal, and in this case, the voltage of the second node N2 may vary. When the first sensing transistor T1′ is turned on, the second initialization voltage AINT provided to the first sensing transistor T1′ may be controlled by the variation of the voltage of the second node N2 and may be provided to the j-th read-out line RXj through the third sensing transistor T3′. Accordingly, a signal sensed by the light sensing element LRE may be output as a sensing signal RS through the j-th read-out line RXj.

FIG. 6 is a cross-sectional view of a portion of the display panel according to one or more embodiments of the present disclosure.

FIG. 6 shows a cross-section of the display element OLED and a portion of the pixel driving circuit PC (refer to FIG. 5) included in the pixel PXij shown in FIG. 5. In FIG. 6, the same reference numerals denote the same elements in FIGS. 2-5, and thus, detailed descriptions of the same elements will be omitted.

FIG. 6 shows the first, fourth, and sixth transistors T1, T4, and T6 of the pixel driving circuit PC of FIG. 5.

The circuit element layer DP-CL may include a buffer layer BFL, first, second, third, fourth, fifth, sixth, and seventh insulating layers INS1, INS2, INS3, INS4, INS5, INS6, and INS7, connection electrodes CNE, and a light shielding layer BML.

The light shielding layer BML may be disposed on the base layer SUB. The light shielding layer BML may overlap the first transistor T1 in the third direction DR3. The light shielding layer BML may include a metal material and may receive a constant voltage. When the constant voltage is provided to the light shielding layer BML, a threshold voltage Vth of the first transistor T1 disposed on the light shielding layer BML may be maintained without varying.

The light shielding layer BML may block a light incident from the bottom of the light shielding layer BML to the first transistor T1. As an example, the light shielding layer BML may include a reflective metal material to reflect the light incident from the bottom of the light shielding layer BML. However, the present disclosure may not be limited thereto or thereby, and the light shielding layer BML may be omitted.

The buffer layer BFL may be disposed on the base layer SUB. The buffer layer BFL may be disposed on the light shielding layer BML to cover the light shielding layer BML. A semiconductor layer SCP1 (or a semiconductor pattern area, hereinafter, referred to as a first semiconductor layer) of the first transistor T1 and a semiconductor layer SCP6 (or a semiconductor pattern area, hereinafter, referred to as a sixth semiconductor layer) of the sixth transistor T6 may be disposed on the buffer layer BFL. The buffer layer BFL may include an inorganic layer.

The first and sixth semiconductor layers SCP1 and SCP6 may include polysilicon, however, the present disclosure may not be limited thereto or thereby. According to one or more embodiments, the first and sixth semiconductor layers SCP1 and SCP6 may include amorphous silicon.

The first and sixth semiconductor layers SCP1 and SCP6 may be formed through the same process, and a portion of each of the first and sixth semiconductor layers SCP1 and SCP6 may be doped with an N-type dopant or a P-type dopant. The first and sixth semiconductor layers SCP1 and SCP6 may include a high-doped region and a low-doped region. The high-doped region may have a conductivity greater than a conductivity of the low-doped region. The high-doped regions may substantially correspond to the source and the drain of the first and sixth transistors T1 and T6. The low-doped region may substantially correspond to the active (or the channel) of the first and sixth transistors T1 and T6.

The high-doped region of the first semiconductor layer SCP1 may include a first source area S1 and a first drain area D1. The low-doped region of the first semiconductor layer SCP1 may be defined as a first channel area A1 and may be defined between the first source area S1 and the first drain area D1. The sixth semiconductor layer SCP6 may include a sixth source area S6, a sixth channel area A6, and a sixth drain area D6.

FIG. 6 shows a structure in which the first semiconductor layer SCP1 is spaced (e.g., spaced apart) from the sixth semiconductor layer SCP6 when viewed in a cross-section, however, the present disclosure may not be limited thereto or thereby. When viewed in the plane (e.g., in a plan view), the first semiconductor layer SCP1 may be provided integrally with the sixth semiconductor layer SCP6. That is, the first semiconductor layer SCP1 and the sixth semiconductor layer SCP6 may be different portions or different areas of one semiconductor pattern.

The first insulating layer INS1 may be disposed on the buffer layer BFL to cover the first and sixth semiconductor layers SCP1 and SCP6.

The first insulating layer INS1 may be disposed on the buffer layer BFL to cover the first and sixth semiconductor layers SCP1 and SCP6. The gate electrodes of the first and sixth transistors T1 and T6 may be disposed on the first insulating layer INS1. The gate electrodes of the first and sixth transistors T1 and T6 may be formed through the same process. Hereinafter, the gate electrode of the first transistor T1 may be referred to as a first gate electrode G1, and the gate electrode of the sixth transistor T6 may be referred to as a sixth gate electrode G6.

The second insulating layer INS2 may be disposed on the first insulating layer INS1 to cover the first and sixth gate electrodes G1 and G6. A dummy electrode DME may be disposed on the second insulating layer INS2. The dummy electrode DME may be disposed on the first gate electrode G1 and may overlap the first gate electrode G1 when viewed in the plane (e.g., in a plan view) or in a cross sectional view. The dummy electrode DME may form the capacitor CST with the first gate electrode G1. In other words, the first gate electrode G1 may correspond to one electrode of the capacitor CST, and the dummy electrode DME may correspond to the other electrode of the capacitor CST.

The third insulating layer INS3 may be disposed on the second insulating layer INS2 to cover the dummy electrode DME. A semiconductor layer SCP4 (or a semiconductor pattern area, hereinafter, referred to as a fourth semiconductor layer) of the fourth transistor T4 may be disposed on the third insulating layer INS3. The fourth semiconductor layer SCP4 may include an oxide semiconductor containing a metal oxide. The oxide semiconductor may include a crystalline and/or amorphous oxide semiconductor.

The fourth semiconductor layer SCP4 may include a plurality of areas distinguished from each other depending on whether the metal oxide is reduced. The area (hereinafter, referred to as a “reduced area”) in which the metal oxide is reduced has a conductivity greater than that of the area (hereinafter, referred to as a “non-reduced area”) in which the metal oxide is not reduced. The reduced areas correspond to a source and a drain of the fourth transistor T4. The non-reduced area substantially corresponds to the active (or the channel) of the fourth transistor T4.

The reduced areas of the fourth semiconductor layer SCP4 may include a fourth source area S4 and a fourth drain area D4. A fourth channel area A4 may be disposed between the fourth source area S4 and the fourth drain area D4.

The fourth insulating layer INS4 may be disposed on the third insulating layer INS3 to cover the fourth semiconductor layer SCP4. A fourth gate electrode G4 of the fourth transistor T4 may be disposed on the fourth insulating layer INS4.

The fifth insulating layer INS5 may be disposed on the fourth insulating layer INS4 to cover the fourth gate electrode G4. The buffer layer BFL and the first to fifth insulating layers INS1 to INS5 may include inorganic layers.

The connection electrode CNE may be disposed between the sixth transistor T6 and the display element OLED. The connection electrode CNE may electrically connect the sixth transistor T6 and the display element OLED. The connection electrode CNE may include a first connection electrode CNE1 and a second connection electrode CNE2 disposed on the first connection electrode CNE1.

The first connection electrode CNE1 may be disposed on the fifth insulating layer INS5 and may be connected to the sixth drain area D6 via a first contact hole CH1 penetrating through the first to fifth insulating layers INS1 to INS5. The sixth insulating layer INS6 may be disposed on the fifth insulating layer INS5 to cover the first connection electrode CNE1. The second connection electrode CNE2 may be disposed on the sixth insulating layer INS6. The second connection electrode CNE2 may be connected to the first connection electrode CNE1 via a second contact hole CH2 penetrating through the sixth insulating layer INS6. The seventh insulating layer INS7 may be disposed on the sixth insulating layer INS6 to cover the second connection electrode CNE2. In the present embodiment, the sixth and seventh insulating layers INS6 and INS7 may include an inorganic layer and/or an organic layer.

The display element OLED may be disposed on the seventh insulating layer INS7. The display element OLED may include a first electrode AE, a second electrode CE, a hole control layer HCL, an electron control layer ECL, and a light emitting layer EML. The first electrode AE may be the anode AE shown in FIG. 5, and the second electrode CE may be the cathode CE shown in FIG. 5. The second electrode CE may be disposed on the first electrode AE, the hole control layer HCL and the electron control layer ECL may be disposed between the first electrode AE and the second electrode CE, and the light emitting layer EML may be disposed between the hole control layer HCL and the electron control layer ECL.

The display area DA may include a light emitting area LEA corresponding to the display element OLED and a non-light-emitting area NLEA adjacent to the light emitting area LEA. The first electrode AE may be disposed on the seventh insulating layer INS7. The first electrode AE may be electrically connected to the second connection electrode CNE2 via a third contact hole CH3 penetrating through the seventh insulating layer INS7.

The pixel definition layer PDL may be disposed on the first electrode AE and the seventh insulating layer INS7 to expose a portion of the first electrode AE. As an example, a display opening PDL-OP1 may be defined through the pixel definition layer PDL to expose the portion of the first electrode AE. The light emitting area LEA may be defined to correspond to the display opening PDL-OP1.

The hole control layer HCL may be disposed on the first electrode AE and the pixel definition layer PDL. The hole control layer HCL may be commonly disposed over the light emitting area LEA and the non-light-emitting area NLEA. The hole control layer HCL may include a hole transport layer and a hole injection layer.

The light emitting layer EML may be disposed on the hole control layer HCL. The light emitting layer EML may be disposed in an area corresponding to the display opening PDL-OP1. The light emitting layer EML may include an organic material and/or an inorganic material. The light emitting layer EML may emit a light having one of red, green, or blue colors.

The electron control layer ECL may be disposed on the light emitting layer EML and the hole control layer HCL. The electron control layer ECL may be commonly disposed over the light emitting area LEA and the non-light-emitting area NLEA. The electron control layer ECL may include an electron transport layer and an electron injection layer.

The second electrode CE may be disposed on the electron control layer ECL. The second electrode CE may be commonly disposed over the pixels PX. That is, the second electrode CE may be a common layer having a single-unit shape and being disposed on the light emitting layers EML of the pixels PX.

Layers from the buffer layer BFL to the seventh insulating layer INS7 may be defined as the circuit element layer DP-CL. The layers on which the display element OLED is disposed may be defined as the display element layer DP-OLED.

The encapsulation layer TFE may be disposed on the display element OLED. The encapsulation layer TFE may include an inorganic layer, an organic layer, and an inorganic layer, which are sequentially stacked. The inorganic layers may include an inorganic material to protect the pixels PX from moisture and/or oxygen, and the organic layer may include an organic material to protect the pixels PX from a foreign substance such as dust particles.

The encapsulation layer TFE may include inorganic layers and an organic layer disposed between the inorganic layers. The inorganic layers may prevent external moisture and/or oxygen from entering the light emitting layer EML and the photoelectric conversion layer OPD (refer to FIG. 7). As an example, the inorganic layers may include silicon nitride, silicon oxide, or a combination thereof. The inorganic layers may be formed through a deposition process.

The organic layer may provide a flat surface. Curves formed on an upper surface of the inorganic layer disposed under the organic layer or particles present on the inorganic layer disposed under the organic layer may be covered by the organic layer to prevent the upper surface of the inorganic layer from having an influence on the components disposed on the organic layer. The organic layer may include an organic material and may be formed through a solution process such as spin coating, slit coating, and/or an inkjet process, etc.

FIG. 7 is a cross-sectional view of a portion of the display panel according to one or more embodiments of the present disclosure.

FIG. 7 shows a cross-section of the light sensing element LRE included in the light sensor SNij shown in FIG. 5 and a portion of the sensor driving circuit SNC (refer to FIG. 5). In FIG. 7, the same reference numerals denote the same elements in FIGS. 2-6, and thus, detailed descriptions of the same elements will be omitted.

FIG. 7 shows the first sensing transistor T1′ and the second sensing transistor T2′ of the sensor driving circuit SNC of FIG. 5.

A semiconductor layer SCP1′ (hereinafter, referred to as a first sensing semiconductor layer) of the first sensing transistor T1′ may be formed through the same process as the first semiconductor layer SCP1 of FIG. 6, and a semiconductor layer SCP2′ (hereinafter, referred to as a second sensing semiconductor layer) of the second sensing transistor T2′ may be formed through the same process as the fourth semiconductor layer SCP4 of FIG. 6. The first sensing semiconductor layer SCP1′ may include a first source area S1′, a first drain area D1′, and a first channel area A1′. The second sensing semiconductor layer SCP2′ may include a second source area S2′, a second drain area D2′, and a second channel area A2′.

The first sensing transistor T1′ may have substantially the same stacked structure as a stacked structure of the first transistor T1 (refer to FIG. 6). The stacked structure of the second sensing transistor T2′ may be substantially the same as a stacked structure of the fourth transistor T4 (refer to FIG. 6). In one or more embodiments, a stacked structure of the third sensing transistor T3′ may be substantially the same as the stacked structure of the first sensing transistor T1′.

A connection electrode CNE′ may include a first connection electrode CNE1′ (or a first sensing connection electrode) and a second connection electrode CNE2′ (or a second sensing connection electrode). The first connection electrode CNE1′ may be disposed on (or at) the same layer as the first connection electrode CNE1 shown in FIG. 6 and may be connected to a first gate electrode G1′ of the first sensing transistor T1′ through a first contact hole CH1′. Hereinafter, the first gate electrode G1′ may be referred to as a first sensing gate electrode G1′ to be distinguished from the first gate electrode G1.

The second connection electrode CNE2′ may be disposed on (or at) the same layer as the second connection electrode CNE2 shown in FIG. 6 and may be connected to the first connection electrode CNE1′ via a second contact hole CH2′ penetrating through the sixth insulating layer INS6.

Referring to FIG. 7, the display area DA may include a light receiving area LRA corresponding to the light sensor SNij and the non-light-emitting area NLEA adjacent to the light receiving area LRA. The non-light-emitting area NLEA may be the non-light-emitting area NLEA shown in FIG. 6.

The light sensing element LRE may include a first electrode AE′, a second electrode CE′, a hole control layer HCL′, an electron control layer ECL′, and a photoelectric conversion layer OPD. The first electrode AE′ may be the anode AE′ shown in FIG. 5, and the second electrode CE′ may be the cathode CE′ shown in FIG. 5. A sensing opening PDL-OP2 may be defined through the pixel definition layer PDL to expose a portion of the first electrode AE′. The light receiving area LRA may correspond to the sensing opening PDL-OP2. The first electrode AE′ may be connected to the second connection electrode CNE2′ via a third contact hole CH3′ penetrating through the seventh insulating layer INS7.

The first electrode AE′ may be formed through the same process as the first electrode AE shown in FIG. 6. The second electrode CE′, the hole control layer HCL′, and the electron control layer ECL′ may be provided integrally with the second electrode CE, the hole control layer HCL, and the electron control layer ECL shown in FIG. 6, respectively. The second electrode CE′ of FIG. 7 and the second electrode CE of FIG. 6 may be areas different from each other in the common layer. The common layer may be deposited using an open mask to have a single-unit shape. The hole control layer HCL′ of FIG. 7 and the hole control layer HCL of FIG. 6 may also be areas different from each other in the common hole control layer, and the electron control layer ECL′ of FIG. 7 and the electron control layer ECL of FIG. 6 may be areas different from each other in the common electron control layer.

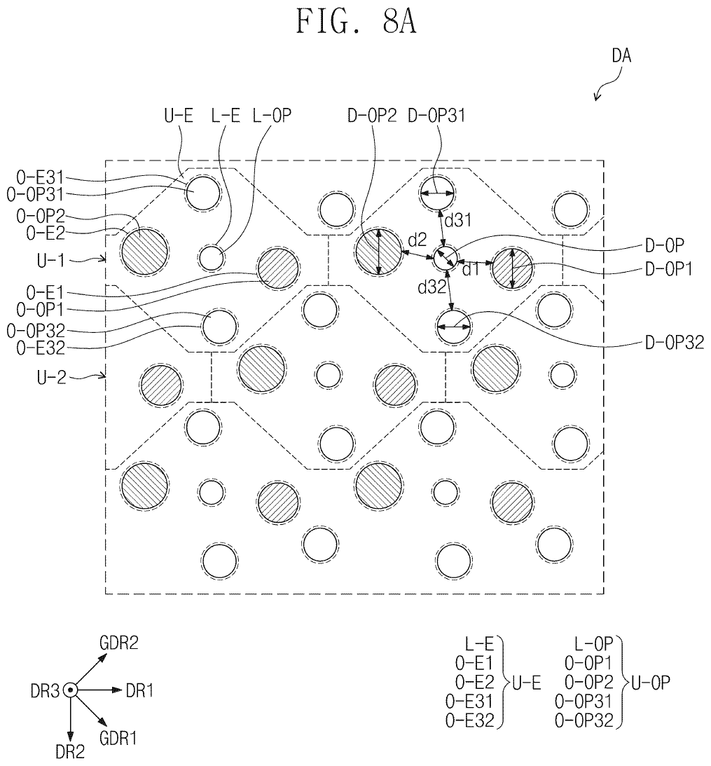

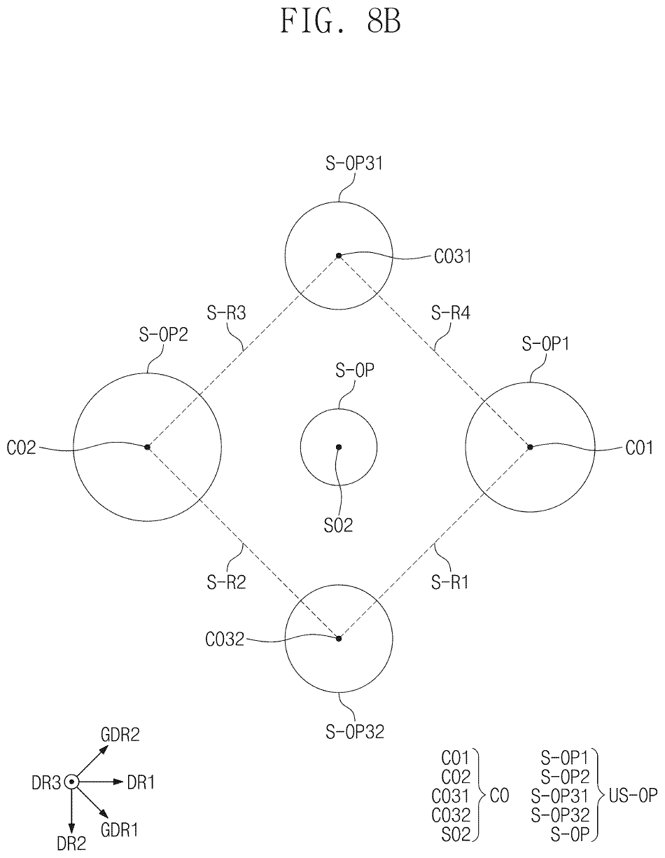

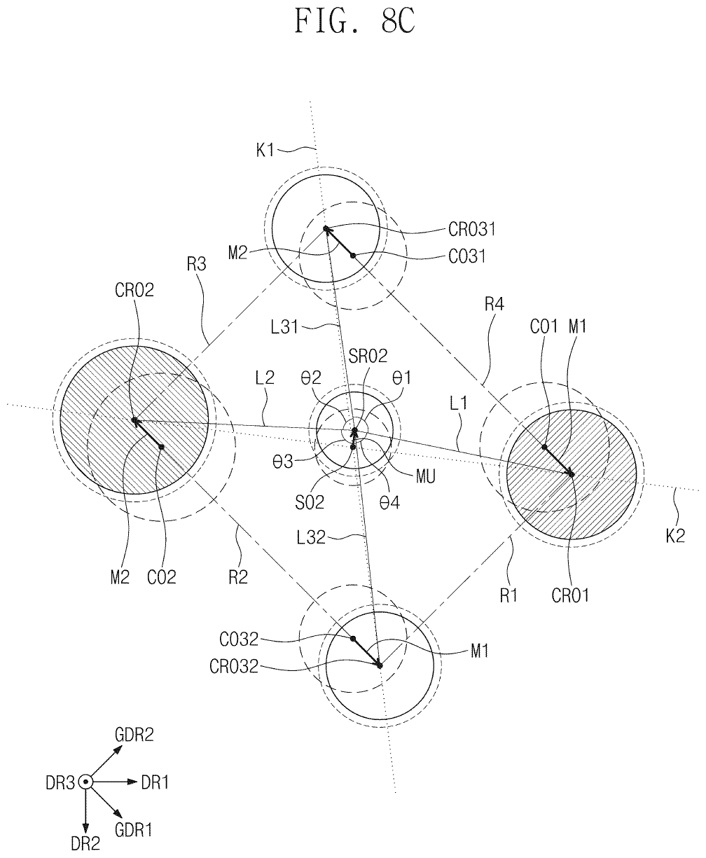

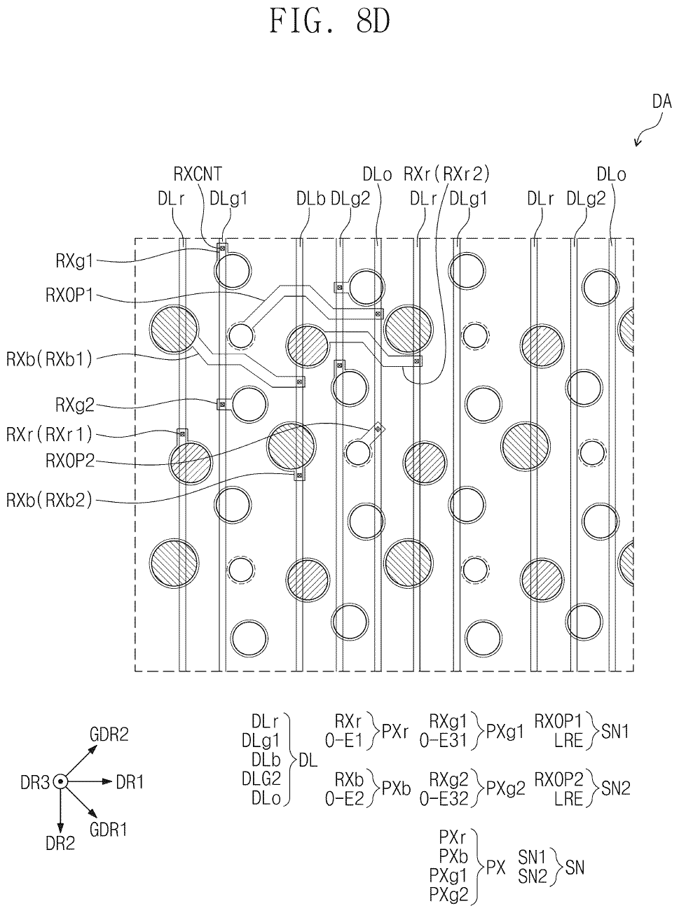

FIG. 8A is a plan view of display openings and sensing openings according to one or more embodiments of the present disclosure. FIG. 8B is a plan view of a reference unit opening according to a comparative example. FIG. 8C is an enlarged plan view of one unit area shown in FIG. 8A.

Hereinafter, the arrangement of the display openings, a reference unit opening, and the sensing openings when viewed in the plane (e.g., in a plan view) will be described with reference to FIGS. 8A-8C.

In FIGS. 8A-8C, for the convenience of explanation, the first electrodes AE (refer to FIG. 6) from among the components included in each of the display elements OLED (refer to FIG. 6) and the first electrodes AE′ (refer to FIG. 7) from among the components included in each of the light sensing elements LRE (refer to FIG. 7) are shown with a circular dotted line. In addition, in the following descriptions with reference to FIGS. 8A-8D, the first electrode AE may be referred to as a display element, and the first electrode AE′ may be referred to as a sensing element.

The display device DD (refer to FIG. 4) may further include a unit element U-E disposed in the display area DA. The unit element U-E may be provided in plural.

The unit elements U-E may be arranged in the display area DA with certain rules. For the convenience of explanation of the arrangement rules of the unit elements U-E, FIG. 8A shows a first row unit element U-1 and a second row unit element U-2. Each of the first row unit element U-1 and the second row unit element U-2 may be provided in plural.

The unit elements U-E may include the first row unit elements U-1 arranged along the first direction DR1 and the second row unit elements U-2 spaced (e.g., spaced apart) from the first row unit elements U-1 in the second direction DR2 and arranged along the first direction DR1 when viewed in the plane (e.g., in a plan view). The second row unit elements U-2 may be shifted from the first row unit elements U-1 to a diagonal direction GDR1 intersecting the first direction DR1 and the second direction DR2.

The first row unit elements U-1 may be alternately arranged with the second row unit elements U-2 within the display area DA along the second direction DR2.

Each of the unit elements U-E may include a first display element O-E1, a second display element O-E2, a third-first display element O-E31, a third-second display element O-E32, and a light sensing element L-E.

Each of the first display element O-E1, the second display element O-E2, the third-first display element O-E31, and the third-second display element O-E32 may correspond to the display element OLED described with reference to FIG. 6. The light sensing element L-E may correspond to the light sensing element LRE described with reference to FIG. 7. Accordingly, details on the same elements will be omitted in order to avoid redundancy.

Each of the first to third-second display elements O-E1 to O-E32 may emit a light. The first display element O-E1 may emit a first color light, the second display element O-E2 may emit a second color light, and the third-first display element O-E31 and the third-second display element O-E32 may emit a third color light. The first color light may have a red color, the second color light may have a blue color, and the third color light may have a green color, however, the present disclosure may not be limited thereto or thereby. According to one or more embodiments, the colors of the first to third color lights may be changed to other colors.

The pixel definition layer PDL (refer to FIGS. 6 and 7) may be provided with a unit opening U-OP defined therethrough. The unit opening U-OP may be provided in plural.

Each of the unit openings U-OP may include a first display opening O-OP1, a second display opening O-OP2, a third-first display opening O-OP31, a third-second display opening O-OP32, and a sensing opening L-OP.

Each of the first to third-second display openings O-OP1 to O-OP32 may correspond to the display opening PDL-OP1 described with reference to FIG. 6. The sensing opening L-OP may correspond to the sensing opening PDL-OP2 described with reference to FIG. 7. Accordingly, details on the same elements will be omitted, and descriptions hereinafter will be focused on different features.

When viewed in the plane, the first to third-second display openings O-OP1 to O-OP32 and the sensing opening L-OP may have a circular shape. For the convenience of explanation, in FIGS. 8A and 8C, each of the first to third-second display openings O-OP1 to O-OP32 and the sensing opening L-OP is shown with a solid circle.

Referring to FIG. 8A, when viewed in the plane (e.g., in a plan view), a second diameter D-OP2 may be greater than a first diameter D-OP1, the first diameter D-OP1 may be greater than a third-first diameter D-OP31, and the third-first diameter D-OP31 may be the same as the third-second diameter D-OP32.

Because an area of a circle is proportional to a square of its diameter when viewed in the plane (e.g., in a plan view), a size of the second display opening O-OP2 may be greater than a size of the first display opening O-OP1, the size of the first display opening O-OP1 may be greater than a size of the third-first display opening O-OP31, and the size of the third-first display opening O-OP31 may be the same as a size of the third-second display opening O-OP32.

Referring to FIG. 8A, each of the first to third-second diameters D-OP1 to D-OP32 may be greater than a diameter D-OP of the sensing opening when viewed in the plane (e.g., in a plan view).

Because an area of a circle is proportional to a square of its diameter when viewed in the plane (e.g., in a plan view), the size of each of the first to third-second display openings O-OP1 to O-OP32 may be greater than a size of the sensing opening L-OP.

Referring to FIG. 8A, the first display opening O-OP1 may overlap the first display element O-E1, the second display opening O-OP2 may overlap the second display element O-E2, the third-first display opening O-OP31 may overlap the third-first display element O-E31, and the third-second display opening O-OP32 may overlap the third-second display element O-E32. The sensing opening L-OP may overlap the light sensing element L-E.

Accordingly, one unit opening U-OP may overlap one unit element U-E corresponding thereto. Accordingly, the arrangement rule of the unit elements U-E in the display area DA may be equally applied to the arrangement of the unit openings U-OP, and thus, details on the same elements will be omitted.

FIG. 8B is a plan view showing an arrangement of a reference unit opening according to a comparative example.

The reference unit opening US-OP is an imaginary opening defined for the convenience of explanation and is defined as an opening with a symmetrical arrangement unlike the unit opening UP-OF according to one or more embodiments of the present disclosure. That is, the reference unit opening US-OP includes a reference sensing opening S-OP, a first reference opening S-OP1, a third-first reference opening S-OP31, a second reference opening S-OP2 arranged symmetrical to the first reference opening S-OP1 with respect to the second direction DR2 with the reference sensing opening S-OP interposed therebetween, and a third-second reference opening S-OP32 arranged symmetrical to the third-first reference opening S-OP31 with respect to the first direction DR1 with the reference sensing opening S-OP interposed therebetween.

When viewed in the plane (e.g., in a plan view), a center of an opening is defined in each of the first to third-second reference openings S-OP1 to S-OP32 and the reference sensing opening S-OP. In one or more embodiments, the center of the opening refers to a center of a circle, which is a planar shape of the opening.

In the present disclosure, for the convenience of explanation, the center of the reference sensing opening S-OP is referred to as a sensing reference center SO2, the center of the first reference opening S-OP1 is referred to as a first reference center CO1, the center of the second reference opening S-OP2 is referred to as a second reference center CO2, the center of the third-first reference opening S-OP31 is referred to as a third-first reference center CO31, and the center of the third-second reference opening S-OP32 is referred to as a third-second reference center CO32.

Each of the centers CO of the reference openings includes the sensing reference center SO2, the first reference center CO1, the second reference center CO2, the third-first reference center CO31, and the third-second reference center CO32.

The reference centers of the centers CO of the reference openings are arranged symmetrical with each other with the sensing reference center SO2 interposed therebetween. That is, the first reference center CO1 is arranged symmetrical to the second reference center CO2 with respect to the second direction DR2 with the sensing reference center SO2 interposed therebetween, and the third-first reference center CO31 is arranged symmetrical to the third-second reference center CO32 with respect to the first direction DR1 with the sensing reference center SO2 interposed therebetween.

Line segments connecting the first reference center CO1, the third-second reference center CO32, the second reference center CO2, and the third-first reference center CO31 form a rhombus. That is, a distance S-R1 between the first reference center CO1 and the third-second reference center CO32, a distance S-R2 between the third-second reference center CO32 and the second reference center CO2, a distance S-R3 between the second reference center CO2 and the third-first reference center CO31, and a distance S-R4 between the third-first reference center CO31 and the first reference center CO1 are substantially the same as each other.

As described above, when the first to third-second reference centers CO1 to CO32 are symmetrically arranged with the sensing reference center SO2 interposed therebetween, distances between the first to third-second reference openings S-OP1 to S-OP32 and a distance between each of the first to third-second reference openings SP-OP1 to S-OP32 and the reference sensing opening S-OP are not sufficiently secured.

That is, when the first to third-second reference openings S-OP1 to S-OP32 are symmetrically arranged to each other and surround the reference sensing opening S-OP as the above comparative example, the distances between the openings are not sufficiently secured, and defects in which connection lines RXr1 to RXg2 (refer to FIG. 8D) overlap the light sensing element LRE (refer to FIG. 7) occur.

Hereinafter, the arrangement rule of the openings included in one unit opening U-OP (refer to FIG. 8A) will be described with reference to FIG. 8C. For the convenience of explanation, the centers CO of the reference openings and the reference unit opening US-OP, which are described with reference to FIG. 8B, are shown in FIG. 8C.

When viewed in the plane (e.g., in a plan view), a center may be defined in each of the first to third-second display openings O-OP1 to O-OP32 and the sensing opening L-OP. In the present disclosure, the center of the opening refers to a center of a circle, which is a planar shape of the opening.

For the convenience of explanation, a center of the sensing opening L-OP may be referred to as a sensing center SRO2, a center of the first display opening O-OP1 may be referred to as a first center CRO1, a center of the second display opening O-OP2 may be referred to as a second center CRO2, a center of the third-first display opening O-OP31 may be referred to as a third-first center CRO31, and a center of the third-second display opening O-OP32 may be referred to as a third-second center CRO32.

According to the present embodiment, the first center CRO1 may be placed at a location that is shifted to a lower right direction M1 with respect to the first reference center CO1. The second center CRO2 may be placed at a location that is shifted to an upper left direction M2 with respect to the second reference center CO2. The third-first center CRO31 may be placed at a location that is shifted to the upper left direction M2 with respect to the third-first reference center CO31. The third-second center CRO32 may be placed at a location that is shifted to the lower right direction M1 with respect to the third-second reference center CO32.

In addition, the sensing center SRO2 may be placed at a location that is shifted to an upper direction MU with respect to the sensing reference center SO2, however, the present disclosure may not be limited thereto or thereby. According to one or more embodiments, the sensing center SRO2 may be placed at a location that is shifted to an upper right direction with respect to the sensing reference center SO2.

The first center CRO1 and the third-second center CRO32 are placed at a lower right position based on the sensing center SRO2. In this case, the expression “the first center CRO1 and the third-second center CRO32 are placed at the lower right position based on the sensing center SRO2” may mean that, when an intersection of an imaginary X-axis line that extends in the first direction DR1 and an imaginary Y-axis line that extends in the second direction DR2 is defined as the sensing center SRO2, the first center CRO1 and the third-second center CRO32 are placed in a fourth quadrant from among quadrants divided by the X-axis line and the Y-axis line.

The second center CRO2 and the third-first center CRO31 are placed at an upper left position. In this case, the expression “the second center CRO2 and the third-first center CRO31 are placed at an upper left position” may mean that, when the intersection of the imaginary X-axis line that extends in the first direction DR1 and the imaginary Y-axis line that extends in the second direction DR2 is defined as the sensing center SRO2, the second center CRO2 and the third-first center CRO31 are placed in a second quadrant from among quadrants divided by the X-axis line and the Y-axis line.

The first center CRO1 and the second center CRO2 may be arranged asymmetrically to each other with respect to the sensing center SRO2. The third-second center CRO32 and the third-first center CRO31 may be arranged asymmetrically to each other with respect to the sensing center SRO2.

In the present embodiment, a first opening distance R1 may correspond to a distance from the first center CRO1 to the third-second center CRO32, a second opening distance R2 may correspond to a distance from the third-second center CRO32 to the second center CRO2, a third opening distance R3 may correspond to a distance from the second center CRO2 to the third-first center CRO31, and a fourth opening distance R4 may correspond to a distance from the third-first center CRO31 to the first center CRO1.

The first center CRO1 and the third-second center CRO32 may be placed at locations that are shifted in the same direction, e.g., the lower right direction M1, with respect to the first reference center CO1 and the third-second reference center CO32, and the second center CRO2 and the third-second center CRO32 may be placed at locations respectively moved in opposite directions to each other, e.g., the upper left direction M2 and the lower right direction M1, with respect to the second reference center CO2 and the third-second reference center CO32. Accordingly, the second opening distance R2 may be greater than the first opening distance R1.

The second center CRO2 and the third-first center CRO31 may be placed at locations moved in the same direction, e.g., the upper left direction M2, with respect to the second reference center CO2 and the third-first reference center CO31, and the second center CRO2 and the third-second center CRO32 may be placed at locations respectively moved in opposite directions to each other, e.g., the upper left direction M2 and the lower right direction M1, with respect to the second reference center CO2 and the third-second reference center CO32. Accordingly, the second opening distance R2 may be greater than the third opening distance R3.

The second center CRO2 and the third-first center CRO31 may be placed at locations that are shifted in the same direction, e.g., the upper left direction M2, with respect to the second reference center CO2 and the third-first reference center CO31, and the third-first center CRO31 and the first center CRO1 may be placed at locations that are respectively shifted in opposite directions to each other, e.g., the upper left direction M2 and the lower right direction M1, with respect to the third-first reference center CO31 and the first reference center CO1. Accordingly, the fourth opening distance R4 may be greater than the third opening distance R3.

The third-first center CRO31 and the first center CRO1 may be placed at locations that are respectively shifted in opposite directions to each other, e.g., the upper left direction M2 and the lower right direction M1, with respect to the third-first reference center CO31 and the first reference center CO1, and the third-second center CRO32 and the first center CRO1 may be placed at locations that are shifted in the same direction, e.g., the lower right direction M1, with respect to the third-second reference center CO32 and the first reference center CO1. Accordingly, the fourth opening distance R4 may be greater than the first opening distance R1.

According to one or more embodiments of the present disclosure, the sensing center SRO2 may be disposed at a right side with respect to an imaginary first diagonal straight line K1 passing through the third-first center CRO31 and the third-second center CRO32 when viewed in the plane. In this case, the expression “the sensing center SRO2 is disposed at the right side with respect to the imaginary first diagonal straight line K1” may mean that, when a plane including the sensing center SRO2 and the first diagonal straight line K1 is divided into two areas by the first diagonal straight line K1, the sensing center SRO2 is disposed in an area where the first center CRO1 is disposed between the two areas. For example, the sensing center SRO2 is disposed in an area of the two areas where the first center CRO1 is disposed.

In addition, the sensing center SRO2 may be disposed at an upper side with respect to an imaginary second diagonal straight line K2 passing through the first center CRO1 and the second center CRO2 when viewed in the plane (e.g., in a plan view). In this case, the expression “the sensing center SRO2 is disposed at the upper side with respect to the imaginary second diagonal straight line K2” may mean that, when a plane including the sensing center SRO2 and the second diagonal straight line K2 is divided into two areas by the second diagonal straight line K2, the sensing center SRO2 is disposed in an area where the third-first center CRO31 is disposed between the two areas. For example, the sensing center SRO2 is disposed in an area of the two areas where the third-first center CRO31 is disposed.

In the present disclosure, a distance between two openings may be defined as a shortest distance between the two openings. In addition, the distance between the two openings may correspond to a width of the pixel definition layer PDL (refer to FIG. 6) disposed between the two openings. The distance between the two openings may correspond to a value obtained by subtracting a radius of each of the two openings from a length of the line segment connecting the centers of the two openings.

In the present disclosure, a distance between the sensing opening L-OP and the first display opening O-OP1 may be defined as a first sensor distance d1, a distance between the sensing opening L-OP and the second display opening O-OP2 may be defined as a second sensor distance d2, a distance between the sensing opening L-OP and the third-first display opening O-OP31 may be defined as a third-first sensor distance d31, and a distance between the sensing opening L-OP and the third-second display opening O-OP32 may be defined as a third-second sensor distance d32. According to one or more embodiments, each of the first to third-second sensor distances d1 to d32 may be equal to or greater than about 16.5 μm and equal to or smaller than about 23 μm.

For the convenience of explanation, imaginary line segments connecting the centers of the openings may be defined.

A first line segment L1 may be defined as a line segment connecting the sensing center SRO2 and the first center CRO1, a second line segment L2 may be defined as a line segment connecting the sensing center SRO2 and the second center CRO2, a third-first line segment L31 may be defined as a line segment connecting the sensing center SRO2 and the third-first center CRO31, and a third-second line segment L32 may be defined as a line segment connecting the sensing center SRO2 and the third-second center CRO32.

Referring to FIG. 8C, the imaginary line segments connecting the centers CRO1 to CRO32 of the first to third-second display openings and the center SRO2 of the sensing opening may form suitable angles (e.g., predetermined angles) according to the arrangement of the first to third-second display elements O-E1 to O-E32 and the light sensing element L-E (e.g., LRE) included in the unit element U-E.

A first angle θ1 between the first line segment L1 and the third-first line segment L31 and a third angle θ3 between the second line segment L2 and the third-second line segment L32 may be an obtuse angle. A second angle θ2 between the second line segment L2 and the third-first line segment L31 and a fourth angle θ4 between the first line segment L1 and the third-second line segment L32 may be an acute angle.

Because the light sensing element L-E (LRE) is surrounded by the first to third-second display elements O-E1 to O-E32 when viewed in the plane (e.g., in a plan view), the sensing opening L-OP may be surrounded by the first to third-second display openings O-OP1 to O-OP32. Accordingly, a sum of the first to fourth angles θ1 to θ4 may be 360°.

A sum of the first angle θ1 and the second angle θ2 may be equal to or greater than 180°, and a sum of the third angle θ3 and the fourth angle θ4 may be equal to or smaller than 180°. In addition, a sum of the second angle θ2 and the third angle θ3 may be equal to or smaller than about 180°, and a sum of the first angle θ1 and the fourth angle θ4 may be equal to or greater than 180°.

FIG. 8D is a plan view showing an arrangement of the openings and the connection lines according to one or more embodiments of the present disclosure. The display area DA shown in FIG. 8D may correspond to the display area DA of FIG. 8A.

Referring to FIG. 8D, a data line DL may be disposed in the display area DA. The data line DL may include a first data line DLr, a second data line DLb, third data lines DLg1 and DLg2, and a sensor data line DLo. The third data lines DLg1 and DLg2 may include a third-first data line DLg1 and a third-second data line DLg2. Each of the first to third data lines DLr, DLb, DLg1, and DLg2 may correspond to one of the data lines (refer to DL1 to DLm of FIG. 4).

When viewed in the plane (e.g., in a plan view), the first to third-second data lines DLr to DLg2 may be arranged in the order of the first data line DLr, the third-first data line DLg1, the second data line DLb, the third-second data line DLg2, and the sensor data line DLo along the first direction DR1. The first to third-second data lines DLr to DLg2 may be arranged spaced (e.g., spaced apart) from each other along the first direction DR1.

Referring to FIG. 8D, the pixels PX may include a first pixel PXr, a second pixel PXb, a third-first pixel PXg1, and a third-second pixel PXg2. Each of the first to third-second pixels PXr to PXg2 may correspond to the pixel PXij described with reference to FIG. 6, and thus, details on the same elements will be omitted.

The first pixel PXr may include a first pixel driving circuit connected to the first data line DLr, a first connection line RXr connected to the first pixel driving circuit, and the first display element O-E1 connected to the first pixel driving circuit through the first connection line RXr1 and disposed on the first pixel driving circuit.

The second pixel PXb may include a second pixel driving circuit connected to the second data line DLb, a second connection line RXb connected to the second pixel driving circuit, and the second display element O-E2 connected to the second pixel driving circuit through the second connection line RXb1 and disposed on the second pixel driving circuit.

The third-first pixel PXg1 may include a third-first pixel driving circuit connected to the third-first data line DLg1, a third-first connection line RXg1 connected to the third-first pixel driving circuit, and the third-first display element O-E31 connected to the third-first pixel driving circuit through the third-first connection line RXg1 and disposed on the third-first pixel driving circuit.

The third-second pixel PXg2 may include a third-second pixel driving circuit connected to the third-second data line DLg2, a third-second connection line RXg2 connected to the third-second pixel PXg2 driving circuit, and the third-second display element O-E32 connected to the third-second pixel driving circuit through the third-second connection line RXg2 and disposed on the third-second pixel driving circuit.

In one or more embodiments, the first to third-second pixel driving circuits may be disposed under the first to third-second display elements O-E1 to O-E32, respectively. Each of the first to third-second pixel driving circuits may correspond to the pixel driving circuit PC described with reference to FIG. 5, and thus, details on the first to third-second pixel driving circuits are omitted.

In the present embodiment, the first to third-second connection lines RXr1 to RXg2 may overlap at least one data line DL when viewed in the plane (e.g., in a plan view). As an example, the second connection line RXb1 may overlap the third-first data line DLg1 and the second data line DLb.

Each of the first to third-second connection lines RXr1 to RXg2 may extend in one direction. Accordingly, each of the first to third-second connection lines RXr1 to RXg2 may be connected to the data line DL that is not adjacent to the display element corresponding thereto.

FIG. 8D shows the structure in which the first pixel PXr includes the first connection line RXr, the second pixel PXb includes the second connection line RXb, the third-first pixel PXg1 includes the third-first connection line RXg1, and the third-second pixel PXg2 includes the third-second connection line RXg2. The first connection line RXr may be provided in the form of the first connection line RXr1 or in the form of a first connection line RXr2. The second connection line RXb may be provided in the form of the second connection line RXb1 or in the form of a second connection line RXb2.

However, the arrangement and shape of each of the first to third-second connection lines RXr1 to RXg2 may not be particularly limited as long as the first to third-second connection lines RXr1 to RXg2 are connected to the first to third-second data lines DLr to DLg2, respectively.

Each of the first to third-second display elements O-E1 to O-E32 (refer to FIG. 8A) may include a first electrode (refer to AE of FIG. 6), a light emitting layer (refer to EML of FIG. 6) disposed on the first electrode AE, and a second electrode (refer to CE of FIG. 6) disposed on the light emitting layer EML.

The first connection line RXr may extend from the first electrode AE (refer to FIG. 6) included in the first display element O-E1 and may be provided integrally with the first electrode AE. The second connection line RXb may extend from the first electrode AE included in the second display element O-E2 and may be provided integrally with the first electrode AE. The third-first connection line RXg1 may extend from the first electrode AE included in the third-first display element O-E31 and may be provided integrally with the first electrode AE. The third-second connection line RXg2 may extend from the first electrode AE included in the third-second display element O-E32 and may be provided integrally with the first electrode AE.

In the present embodiment, the first data line DLr may be a red data line to which red data signals to drive the first pixel PXr are applied. The second data line DLb may be a blue data line to which blue data signals to drive the second pixel PXb are applied. The third data lines DLg1 and DLg2 may be green data lines to which green data signals to drive the third pixels are applied. However, the data signals transmitted through the first to third data lines DLr to DLg2 may not be limited thereto or thereby.

Referring to FIG. 8D, light sensors SN may include a first light sensor SN1 and a second light sensor SN2. Each of the first and second light sensors SN1 and SN2 may correspond to the light sensor SNij described with reference to FIG. 7, and thus, details on the first and second light sensors SN1 and SN2 are omitted.

The first light sensor SN1 may include a sensor driving circuit connected to the sensor data line DLo, a first sensor connection line RXOP1 connected to the sensor driving circuit, and a light sensing element (refer to LRE of FIG. 7) connected to the sensor driving circuit through the first sensor connection line RXOP1 and disposed on the sensor driving circuit.

The second light sensor SN2 may include a sensor driving circuit connected to the sensor data line DLo, a second sensor connection line RXOP2 connected to the sensor driving circuit, and a light sensing element (refer to LRE of FIG. 7) connected to the sensor driving circuit through the second sensor connection line RXOP2 and disposed on the sensor driving circuit.

Each of the sensor connection lines RXOP1 and RXOP2 may extend from a first electrode (refer to AE′ of FIG. 7) included in the light sensing element LRE and may be provided integrally with the first electrode AE′. The sensor data line DLo may be a data line to which data signals to drive the sensor are applied.

In the present embodiment, the first sensor connection line RXOP1 and the second sensor connection line RXOP2 may have different shapes, however, the present disclosure may not be limited thereto or thereby. As an example, the first sensor connection line RXOP1 and the second sensor connection line RXOP2 may have the same shape. In this case, the first light sensor SN1 and the second light sensor SN2 may correspond to the same light sensor.

Each of the first to third-second connection lines RXr1 to RXg2 may be disposed on a different layer from a corresponding pixel driving circuit from among the first to third-second pixel driving circuits. However, a contact hole may be formed through at least a portion of the circuit element layer DP-CL to overlap a connection part of the first to third-second connection lines RXr1 to RXg2. Accordingly, the connection part of the first to third-second connection lines RXr1 to RXg2 may be connected to the corresponding pixel driving circuit from among the first to third-second pixel driving circuits via the contact hole formed through at least the portion of the circuit element layer DP-CL.

The data signal transmitted through each of the data lines DLr to DLg2 may be convert to a current by the pixel driving circuit connected to the corresponding data line and may be applied to the display element connected to the pixel driving circuit.

As described above, when each of the data lines receives only data signals about one color information, an overall power consumption may be reduced. As an example, the power consumption may be reduced compared to the case where the red data signals and the blue data signals are alternately applied to one data line.

In the present embodiment, the connection lines RXr1 to RXg2 may not overlap the light sensing element LRE (refer to FIG. 7).

When the light sensing element LRE is surrounded by the first to third-second display elements O-E1 to O-E32, the first to third-second sensor distances d1 to d32 (refer to FIG. 8A) and the first to fourth opening distances R1 to R4 described with reference to FIGS. 8A and 8C may not sufficiently secured, and as a result, defects where the first to third-second connection lines RXr1 to RXg2 overlap the light sensing element LRE may occur.

However, according to the present embodiment, because locations of the first to third-second display elements O-E1 to O-E32 and the light sensing element LRE when viewed in the plane are optimized, the first to third-second sensor distances d1 to d32 may be adjusted. That is, the first to third-second display elements O-E1 to O-E32 may be arranged asymmetrically based on the light sensing element LRE, and the distances between the first to third-second display elements O-E1 to O-E32 and the light sensing element LRE may be sufficiently secured.

Accordingly, the complexity of a pixel layout may be reduced and the defects of the first to third-second connection lines RXr1 to RXg2 overlapping with the light sensing element LRE may be prevented.

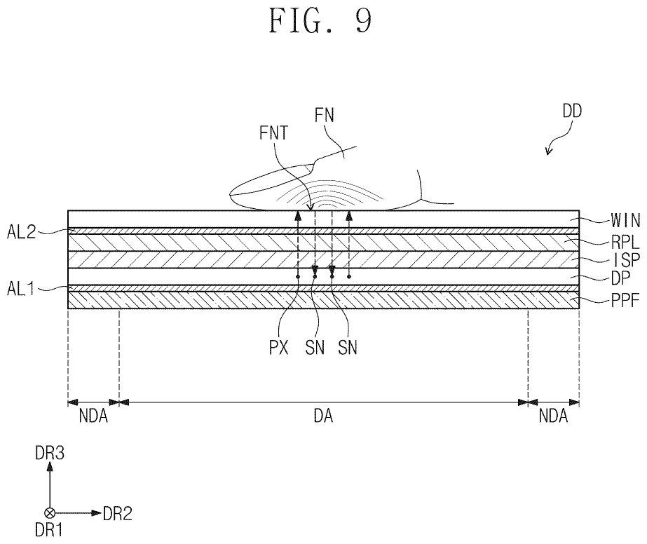

FIG. 9 is a cross-sectional view illustrating a process of obtaining fingerprint information that is biometric information using light sensors. In FIG. 9, the same reference numerals denote the same elements in FIG. 2, and thus, detailed descriptions of the same elements will be omitted.

Referring to FIG. 9, the display device DD may include a plurality of the light sensors SN. Each of the light sensors SN may have the same structure as the light sensor SNij shown in FIGS. 5 and 7.

The light sensors SN may sense a fingerprint FNT of a finger FN provided on the display panel DP. The light emitted from the light emitting elements OLED (refer to FIG. 6) of the pixels PX may be provided to and reflected by the fingerprint FNT. The fingerprint FNT may have a shape defined by valleys and ridges, and a light reflectance of the valleys is different from a light reflectance of the ridges. The plural light sensors SN may receive the light reflected from the valleys or ridges depending on their location. The information about the fingerprint FNT may be obtained using information sensed by the light sensors SN.

In the present embodiment, the light sensors SN sense the fingerprint information of the user, however, the present disclosure may not be particularly limited as long as the information is secured by sensing the light. As an example, the light sensors SN may sense pulse information of the user.

Although the embodiments of the present disclosure have been described, it is understood that the present disclosure may not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present disclosure shall be determined according to the attached claims and their equivalents.

What is claimed is:

1. A display device comprising:
a base layer comprising a display area and a non-display area adjacent to the display area;
unit elements, each of the unit elements comprising a first display element configured to emit a first color light, a second display element configured to emit a second color light different from the first color light, a third-first display element configured to emit a third color light different from the first and second color lights, a third-second display element configured to emit the third color light different from the first and second color lights, and a light sensing element surrounded by the first, second, third-first, and third-second display elements and located in the display area; and
a pixel definition layer, first, second, third-first, and third-second display openings in the pixel defining layer and overlapping the first, second, third-first, and third-second display elements and a sensing opening in the pixel defining layer and overlapping the light sensing element, wherein the first, second, third-first, and third-second display openings and the sensing opening have a circular shape when viewed in a plane, a center of the first display opening and a center of the third-second display opening are at a lower right position with respect to the sensing opening, and a center of the second display opening and a center of the third-first display opening are at an upper left position with respect to the sensing opening.

2. The display device of claim 1, wherein the center of the first display opening and the center of the third-second display opening are asymmetrically located with respect to the sensing opening, and the center of the second display opening and the center of the third-first display opening are asymmetrically located with respect to the sensing opening.

3. The display device of claim 1, wherein a distance from the center of the second display opening to the center of the third-first display opening is smaller than a distance from the center of the second display opening to the center of the third-second display opening when viewed in the plane, and a distance from the center of the first display opening to the center of the third-first display opening is greater than a distance from the center of the first display opening to the center of the third-second display opening when viewed in the plane.

4. The display device of claim 1, wherein a distance from the center of the second display opening to the center of the third-first display opening is smaller than a distance from the center of the first display opening to the center of the third-first display opening when viewed in the plane, and a distance from the center of the second display opening to the center of the third-second display opening is greater than a distance from the center of the first display opening to the center of the third-second display opening when viewed in the plane.

5. The display device of claim 1, wherein the center of the sensing opening is at a right side with respect to an imaginary line passing through the center of the third-first display opening and the center of the third-second display opening when viewed in the plane.

6. The display device of claim 1, wherein the center of the sensing opening is at an upper side with respect to an imaginary line passing through the center of the first display opening and the center of the second display opening when viewed in the plane.

7. The display device of claim 1, wherein the unit elements comprise:
first row unit elements arranged along a first direction when viewed in the plane; and
second row unit elements spaced from the first row unit elements in a second direction intersecting the first direction and arranged along the first direction when viewed in the plane, and the second row unit elements are shifted from the first row unit elements along a diagonal direction intersecting the first and second directions.

8. The display device of claim 1, wherein the second display opening has a diameter greater than a diameter of the first display opening when viewed in the plane, the first display opening has the diameter greater than a diameter of the third-first display opening when viewed in the plane, and the diameter of the third-first display opening is equal to a diameter of the third-second display opening when viewed in the plane.

9. The display device of claim 1, wherein each of the first, second, third-first, and third-second display openings has a diameter greater than a diameter of the sensing opening when viewed in the plane.

10. The display device of claim 1, wherein a distance between the sensing opening and each of the first, second, third-first, and third-second display openings is equal to or greater than about 16.5 micrometers and equal to or smaller than about 23 micrometers when viewed in the plane.

11. The display device of claim 1, wherein a distance from the center of the third-first display opening to the center of the sensing opening is different from a distance from the center of the third-second display opening to the center of the sensing opening when viewed in the plane.

12. The display device of claim 1, further comprising first, second, third-first, and third-second connection lines, wherein each of the first, second, third-first, and third-second display elements comprises a first electrode, a light emitting layer on the first electrode, and a second electrode on the light emitting layer, each of the first, second, third-first, and third-second connection lines extends from the first electrode of a corresponding display element from among the first, second, third-first, and third-second display elements, and the first, second, third-first, and third-second connection lines do not overlap the light sensing element.

13. The display device of claim 12, further comprising first, second, third-first, and third-second driving circuits and first, second, third-first, and third-second data lines, wherein the first, second, third-first, and third-second data lines are connected to the first, second, third-first, and third-second driving circuits, respectively, and the first, second, third-first, and third-second connection lines are connected to the first, second, third-first, and third-second driving circuits, respectively.

14. The display device of claim 1, further comprising:
a sensor data line;
a sensor driving circuit connected to the sensor data line; and
a sensor connection line connecting the light sensing element and the sensor driving circuit.

15. The display device of claim 1, wherein the first color light is a red light, the second color light is a blue light, and the third color light is a green light.

16. The display device of claim 1, wherein the light sensing element senses fingerprint information or pulse information.

17. A display device comprising:
a base layer comprising a display area and a non-display area adjacent to the display area;
unit elements, each of the unit elements comprising a first display element, a second display element, a third-first display element, a third-second display element, and a light sensing element surrounded by the first, second, third-first, and third-second display elements and located in the display area; and
a pixel definition layer, first, second, third-first, and third-second display openings in the pixel defining layer and respectively overlapping the first, second, third-first, and third-second display elements, and a sensing opening in the pixel defining layer and overlapping the light sensing element, wherein the first, second, third-first, and third-second display openings and the sensing opening have a circular shape when viewed in a plane, and each of a first angle between a first line segment connecting a center of the sensing opening and a center of the first display opening and a third-first line segment connecting the center of the sensing opening and a center of the third-first display opening and a third angle between a second line segment connecting the center of the sensing opening and a center of the second display opening and a third-second line segment connecting the center of the sensing opening and a center of the third-second display opening is an obtuse angle.

18. The display device of claim 17, wherein each of a second angle between the second line segment and the third-first line segment and a fourth angle between the first line segment and the third-second line segment is an acute angle.

19. The display device of claim 17, wherein a sum of the first to fourth angles is 360 degrees, and wherein a sum of the first angle and the second angle is equal to or greater than 180 degrees, and a sum of the third angle and the fourth angle is equal to or smaller than 180 degrees.

20. A electronic device comprising:
a display device comprising:
a base layer comprising a display area and a non-display area adjacent to the display area;
unit elements, each of the unit elements comprising a first display element configured to emit a first color light, a second display element configured to emit a second color light different from the first color light, a third-first display element configured to emit a third color light different from the first and second color lights, a third-second display element configured to emit the third color light different from the first and second color lights, and a light sensing element surrounded by the first, second, third-first, and third-second display elements and located in the display area; and
a pixel definition layer, first, second, third-first, and third-second display openings in the pixel defining layer and overlapping the first, second, third-first, and third-second display elements and a sensing opening in the pixel defining layer and overlapping the light sensing element, wherein the first, second, third-first, and third-second display openings and the sensing opening have a circular shape when viewed in a plane, a center of the first display opening and a center of the third-second display opening are at a lower right position with respect to the sensing opening, and a center of the second display opening and a center of the third-first display opening are at an upper left position with respect to the sensing opening, and
A window disposed on the display device.
